(19) United States
(12) Patent Application Publication
(10) Pub. No.: US 2021/0193658 A1
(43) Pub. Date: Jun. 24, 2021

(54) INTEGRATED DEVICE WITH DEEP PLUG UNDER SHALLOW TRENCH

(71) Applicant: STMicroelectronics S.r.l., Agrate Brianza (MB), OT (IT)

(72) Inventors: Andrea PALEARI, Brugherio (MB) (IT); Simone Dario MARIANI, Vedano al Lambro (MB) (IT); Irene BALDI, Milano (IT); Daniela BRAZZELLI, Busto Arsizio (VA) (IT); Alessandra Piera MERLINI, Albiate (MB) (IT)

(73) Assignee: STMicroelectronics S.r.l., Agrate Brianza (MB), OT (IT)

(21) Appl. No.: 17/124,671

(22) Filed: Dec. 17, 2020

(30) Foreign Application Priority Data
Dec. 18, 2019 (IT) 102019000024532

(51) Int. Cl. H01L 27/092; H01L 21/762

(52) U.S. Cl. CPC H01L 27/0922; H01L 21/76224

(57) ABSTRACT

An integrated device includes a deep plug. The deep plug is formed by a deep trench extending in a semiconductor body from a shallow surface of a shallow trench isolation. A trench contact makes contact with a conductive filler of the deep trench through the shallow trench at its shallow surface. A system includes at least one integrated device with the deep plug. Moreover, a corresponding process for manufacturing this integrated device includes steps for forming and filling the deep trench before forming the shallow trench isolation and trench window through which the trench contact extends to make contact with the conductive filler. The semiconductor body has a thickness, and the deep trench extends into the semiconductor body less than the thickness.

### PRIORITY CLAIM

This application claims the priority benefit of Italian Application for Patent No. 102019000024532, filed on Dec. 18, 2019, the content of which is hereby incorporated by reference in its entirety to the maximum extent allowable by law.

### TECHNICAL FIELD

The present disclosure relates to the field of integrated devices. More specifically, this disclosure relates to deep plugs.

### BACKGROUND

The background of the present disclosure is hereinafter introduced with the discussion of techniques relating to its context. However, even when this discussion refers to documents, acts, artifacts and the like, it does not suggest or represent that the discussed techniques are part of the prior art or are common general knowledge in the field relevant to the present disclosure.

Deep trenches are commonly used in integrated devices to reach deep regions of chips wherein they are integrated (for example, their substrates). The deep trenches may be filled with (electrically) insulating material; in this case, the deep trenches are used in Deep Trench Isolation (DTI) techniques to (deeply) insulate different regions of each chip. The deep trenches may also be coated with (electrically) insulating material on their lateral surfaces and then filled with (electrically) conductive material; in this case, the deep trenches are used as deep plugs to (electrically) contact the deep regions of each chip from its front surface. For example, the deep plugs are commonly used to bias a substrate of the chip, to collect parasitic currents from the substrate and so on.

Generally, each deep trench (when used as deep plug) is formed by etching the chip from the front surface (through a corresponding mask) until reaching a desired depth. The trench is then coated with the insulating material (opened at its bottom with a dedicated step) and filled with the conductive material. In the end, the insulating material is planarized until reaching the front surface of the chip.

However, the deep plugs require dedicated design rules.

Particularly, the planarization of the conductive material filling the deep trenches is quite difficult to control accurately (on the deep trench and around it). Therefore, this conductive material generally exhibits a bulge or a recess at the front surface. The non-planarity of the conductive material filling the deep trench causes a risk of leaving conductive residues on the front surface of the chip due to the following process steps.

The corresponding electric field generated around the deep plugs at the front surface of the chip may interfere with operation of components integrated on the same chip. This reduces the performance and reliability of the integrated device (for example, with increased defectiveness and risk of breakdown thereof).

Therefore, in order to ensure correct operation of these components, they are generally spaced apart from the deep plugs on the front surface by corresponding guard regions. However, the guard regions (wherein no components are integrated) waste area of the chip; this adversely affects a size of the integrated device.

### SUMMARY

A simplified summary of the present disclosure is herein presented in order to provide a basic understanding thereof; however, the sole purpose of this summary is to introduce some concepts of the disclosure in a simplified form as a prelude to its following more detailed description, and it is not to be interpreted as an identification of its key elements nor as a delineation of its scope.

In general terms, the present disclosure is based on the idea of forming the deep plug under a shallow trench.

Particularly, an aspect provides an integrated device comprising a deep plug. The deep plug comprises a deep trench extending in a semiconductor body from a shallow surface of a shallow trench, and a trench contact contacting a conductive filler of the deep trench through the shallow trench at its shallow surface.

A further aspect provides a system comprising at least one integrated device as above.

A further aspect provides a corresponding process for manufacturing this integrated device.

More specifically, one or more aspects of the present disclosure are set out in the independent claims and advantageous features thereof are set out in the dependent claims, with the wording of all the claims that is herein incorporated verbatim by reference (with any advantageous feature provided with reference to any specific aspect that applies mutatis mutandis to every other aspect).

### BRIEF DESCRIPTION OF THE DRAWINGS

The solution of the present disclosure, as well as further features and the advantages thereof, will be best understood with reference to the following detailed description thereof, given purely by way of a non-restrictive indication, to be read in conjunction with the accompanying drawings (wherein, for the sake of simplicity, corresponding elements are denoted with equal or similar references and their explanation is not repeated, and the name of each entity is generally used to denote both its type and its attributes, like value, content and representation). In this respect, it is expressly intended that the drawings are not necessary drawn to scale (with some details that may be exaggerated and/or simplified) and that, unless otherwise indicated, they are merely used to illustrate the structures and procedures described herein conceptually. Particularly:

FIG. 1 shows a schematic representation in cross-section view of an integrated device according to an embodiment of the present disclosure;

FIG. 2A-FIG. 2J show the main steps of a manufacturing process of the integrated device according to an embodiment of the present disclosure;

FIG. 3 shows a schematic representation in cross-section view of a further integrated device according to an embodiment of the present disclosure;

FIG. 4A-FIG. 4B show the main steps of a manufacturing process of the further integrated device according to an embodiment of the present disclosure; and

FIG. 5 shows a schematic block diagram of a system incorporating the integrated device according to an embodiment of the present disclosure.

### DETAILED DESCRIPTION

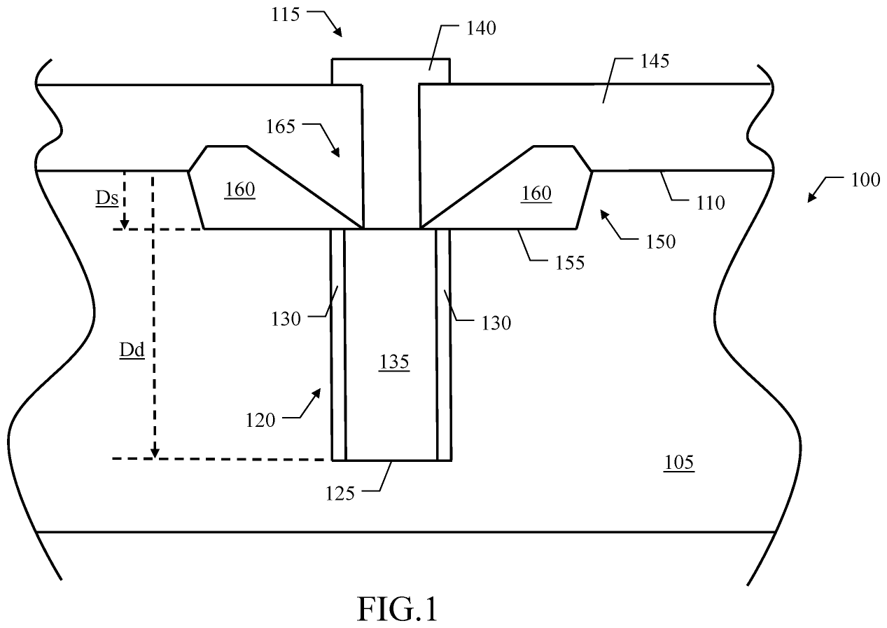

With reference in particular to FIG. 1, a schematic representation is shown in cross-section view of an integrated device 100 according to an embodiment of the present disclosure.

The integrated device 100 is integrated on a semiconductor body, for example, a chip (or die or layer) 105 of semiconductor material (such as silicon) having a certain thickness. The chip 105 has a (main) front surface 110 (used to contact components integrated on the chip 105, not shown in the figure).

The integrated device 100 comprises a deep plug 115 (or more), which is used to (electrically) contact the chip 105 deeply (for example, to bias a substrate of the chip 105, not indicated in the figure, to collect parasitic currents from the substrate and so on). The deep plug 115 comprises a deep trench 120. The deep trench 120 extends (deeply) in the chip 105 to a (deep) depth Dd from the front surface 110 that is less than the thickness. The deep trench 120 has a deep (bottom) surface 125 at the depth Dd (buried within the chip 105) and a lateral (side) surface coated with an insulating coating 130 of (electrically) insulating material (such as silicon oxide), but where the bottom of the deep trench is not coated; the (coated) deep trench 120 is then filled with a conductive filler 135 of (electrically) conductive material (such as doped polysilicon) so that the conductive filler makes physical and electrical contact with the chip 105 at the bottom of the deep trench 120. A trench contact 140 of (electrically) conductive material (such as metal) is provided for contacting the conductive filler 135. For this purpose, the trench contact 140 crosses a corresponding window being opened across a protective layer 145 of (electrically) insulating material (for example, silicon dioxide) covering the whole chip 105 (on the front surface 110).

The integrated device 100 further comprises a shallow trench 150 (or more). The shallow trench 150 extends in the chip 105 from the front surface 110 to a (shallow) depth Ds; the depth Ds is (strictly) less than the depth Dd, for example, with the depth Dd equal to 5-100 times the depth Ds. The shallow trench 150 has a shallow (bottom) surface 155 at the depth Ds (buried less deeply within the chip 105 than the deep surface 125). The shallow trench 150 is filled with an insulating filler 160 of (electrically) insulating material (such as silicon oxide). The shallow trenches are commonly used in Shallow Trench Isolation (STI) techniques to (shallowly) insulate different regions of each chip (and particularly to prevent current leakage between adjacent components in the chip).

In the solution according to an embodiment of the present disclosure, the deep trench 120 extends in the chip 105 from the shallow surface 155 (of the shallow trench 150) to the depth Dd. Moreover, the trench contact 140 contacts the conductive filler 135 through the shallow trench 150 at its shallow surface 155. For this purpose, the trench contact 140 crosses a (trench) window 165 being opened across the (filled) shallow trench 150.

The above-described solution does not require dedicated design rules for the deep plug 115.

Indeed, in this case there is no risk of leaving conductive residues on the front surface 110. This avoids (or at least substantially reduces) any interference with operation of components integrated on the chip 105. Therefore, no guard region (or at least a very narrow one) is required around the deep plug 115. All of the above involves a significant saving of area of the chip 105, with a beneficial effect on a size of the integrated device 100 (at the same time, without any degradation of performance and reliability thereof).

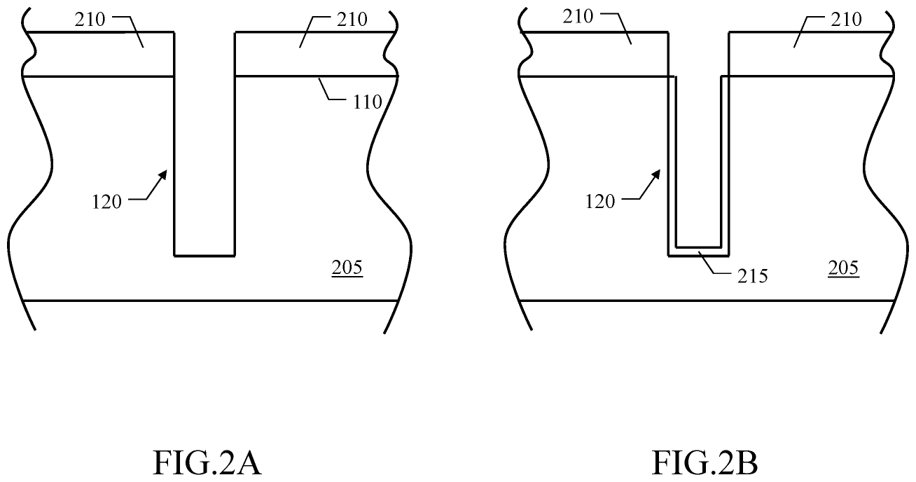

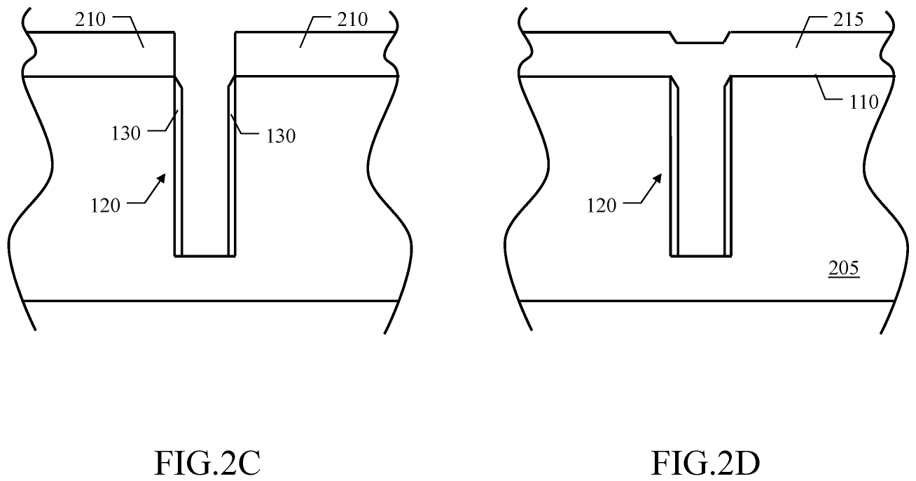

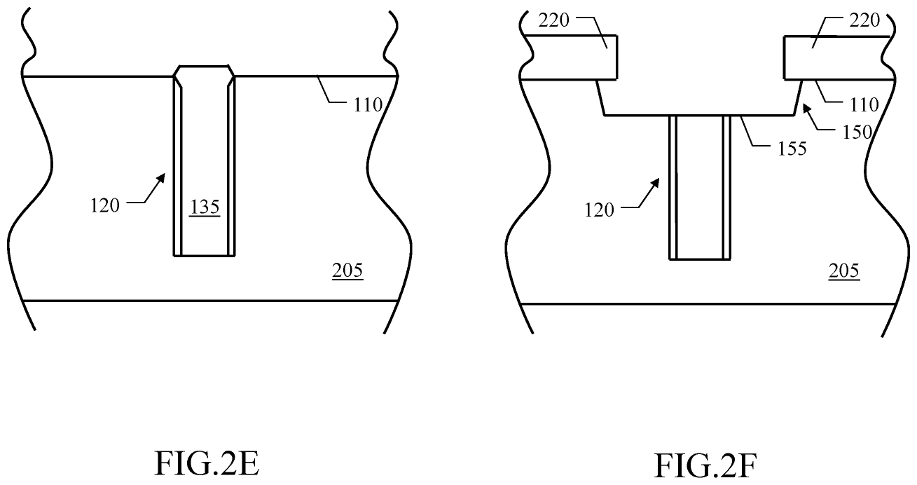

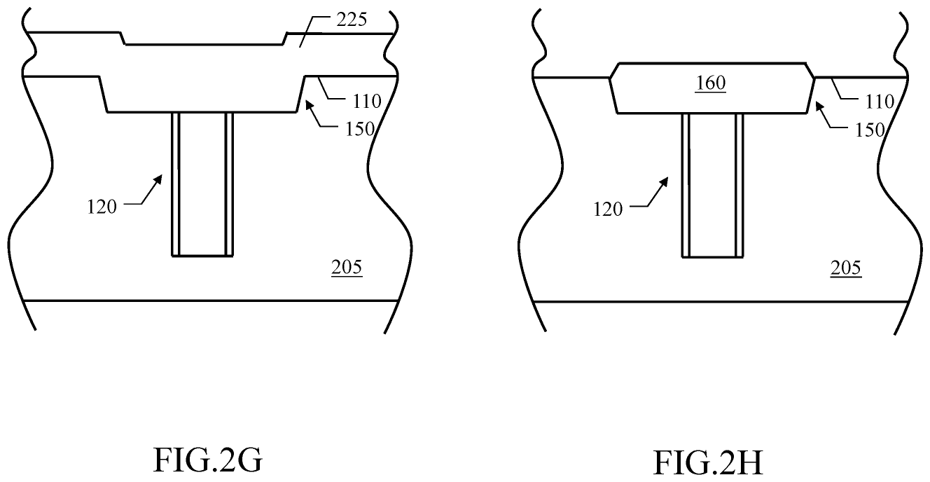

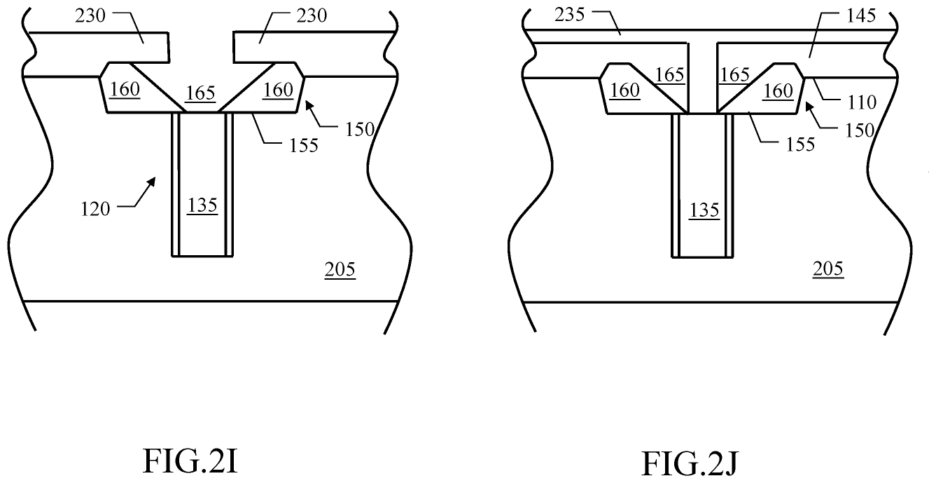

With reference now to FIG. 2A-FIG. 2J, the main steps are shown of a manufacturing process of the integrated device according to an embodiment of the present disclosure.

Starting from FIG. 2A, the manufacturing process is performed at the level of a wafer (or layer) 205 of semiconductor material having a thickness, wherein the same structure is integrated simultaneously in a large number of identical areas thereof (only one referred to in the following for the sake of simplicity). A mask 210 for the deep trench is formed (for example, with photo-lithographic techniques) on a front surface of the wafer 205 which will define the front surface of the corresponding chip and then is denoted with the same reference 110. The wafer 205 is etched through the mask 210 (for example, with dry etching techniques) to form the deep trench 120 which does not extend completely through the thickness of wafer 205.

Moving to FIG. 2B, the deep trench 120 is coated with an insulating layer 215 (for example, silicon oxide grown with thermal oxidation techniques on any surfaces of the wafer 205 being exposed through the mask 210).

Moving to FIG. 2C, the insulating layer is selectively etched through the mask 210 (for example, with dry etching techniques); the process removes the insulating layer at the bottom of the deep trench 120 (with a negligible removal thereof at the top of its lateral surface), so as to leave the insulating coating 130.

Moving to FIG. 2D, the mask is stripped. A conductive layer 215 (for example, of doped polysilicon) is deposited onto the wafer 205 so as to fill the (coated) deep trench 120 and to cover the front surface 110 and further make physical and electrical contact with the wafer 205 at the bottom of the deep trench.

Moving to FIG. 2E, the wafer 205 is planarized (for example, with chemical-mechanical polishing (CMP) techniques) to remove an excess of the conductive layer from the front surface 110, until leaving the deep trench 120 filled with the (remaining) conductive layer that defines the conductive filler 135. The planarization of the deep trench 120 might be irregular, as represented in the figure with an (exaggerated) bulge of the conductive filler 135.

Moving to FIG. 2F, a further mask 220 for defining the shallow trench is formed (for example, with photolithographic techniques) onto the wafer 205; the mask 220 leaves exposed the (filled) deep trench 120 and a portion of the front surface 110 around it (centered on the deep trench 120). The wafer 205 is etched through the mask 220 (for example, with dry etching techniques) to form the shallow trench 150. This operation removes a corresponding (upper) portion of the deep trench 120 extending from the front surface 110 to the shallow surface 155, so that any irregularities due to its planarization automatically disappear. As a result, the remaining (lower) deep trench 120 extends in the wafer 205 from the shallow surface 155.

It will be noted that the trench sidewall (extending between surface 110 and surface 115) forms a first angle with the surface 155.

Moving to FIG. 2G, the mask is stripped. An insulating layer 225 (for example, of silicon oxide) is deposited (possibly after a thermal oxidation step) onto the wafer 205 so as to fill the shallow trench 150 (thereby covering the deep trench 120 as well) and to cover the front surface 110 (possibly covered by a layer of silicon nitride, not shown in the figure).

Moving to FIG. 2H, the wafer 205 is planarized (for example, with CMP techniques) to remove an excess of the insulating layer from the front surface 110, until leaving the shallow trench 150 filled with the (remaining) insulating layer that defines the insulating filler 160. In this case as well, the planarization of the shallow trench 150 might be irregular, as represented in the figure with an (exaggerated) bulge of the insulating filler 160. As a result, the (filled) deep trench 120 is coaxial with the (filled) shallow trench 150 (perpendicularly to the front surface 110). The shallow trench 150 has a transversal cross-section (in any plane parallel to the front surface 110) which is larger than the one of the deep trench 120 (for example, 2-4 times), so that in plan view the shallow trench 150 surrounds the deep trench 120 completely.

Moving to FIG. 2I, a further mask 230 is formed (for example, with photolithographic techniques) onto the wafer 205; the mask 230 leaves exposed a central portion of the shallow trench 150 for contacting the deep trench 120. The insulating filler 160 is etched through the mask 230 (for example, with wet etching techniques) until reaching the deep trench 120, thereby forming the corresponding trench window 165. The trench window 165 is coaxial with the deep trench 120 (perpendicularly to the front surface 110). The trench window 165 has a transversal cross-section (in any plane parallel to the front surface 110) which is smaller than the one of the deep trench 120, so that the trench window 165 only exposes a central portion of the conductive filler 135 of the deep trench 120 at the shallow surface 155 (for example, 70-80% thereof).

It will be noted that the side wall of the trench window 165 (formed by the etched surface of the filler 135) forms a second angle with the surface 155. This second angle is different from the first angle for the sidewall of the shallow trench 150, and in particular the first angle is steeper than the second angle.

Moving to FIG. 2J, the protective layer 145 is deposited on the wafer 205 so as to fill the trench window 165 and to cover the (remaining) insulating filler 160 and the front surface 110. The protective layer 145 is removed selectively (for example, with dry etching techniques through a corresponding mask, not shown in the figure) to form a window (coaxial with the deep trench 120 perpendicularly to the front surface 110), which exposes the central portion of the conductive filler 135 (begin exposed at the shallow surface 155 by the trench window 165). A metal layer 235 (for example, of copper) is deposited on the wafer 205 so as to fill the window exposing the conductive filler 135 and to cover the protective layer 145. In this way, the whole conductive filler 135 being exposed is contacted, with the rest thereof that is protected by the shallow trench 150 (thereby further increasing performance and reliability). The metal layer 235 is selectively removed (for example, with dry etching techniques through a corresponding mask, not shown in the figure) to form the trench contact, thereby obtaining the desired structure (as shown in FIG. 1). At this point (after possible other metal levels required by the integrated device), the areas of the wafer 205 (wherein the same structures are formed) are separated into corresponding chips through a cutting operation.

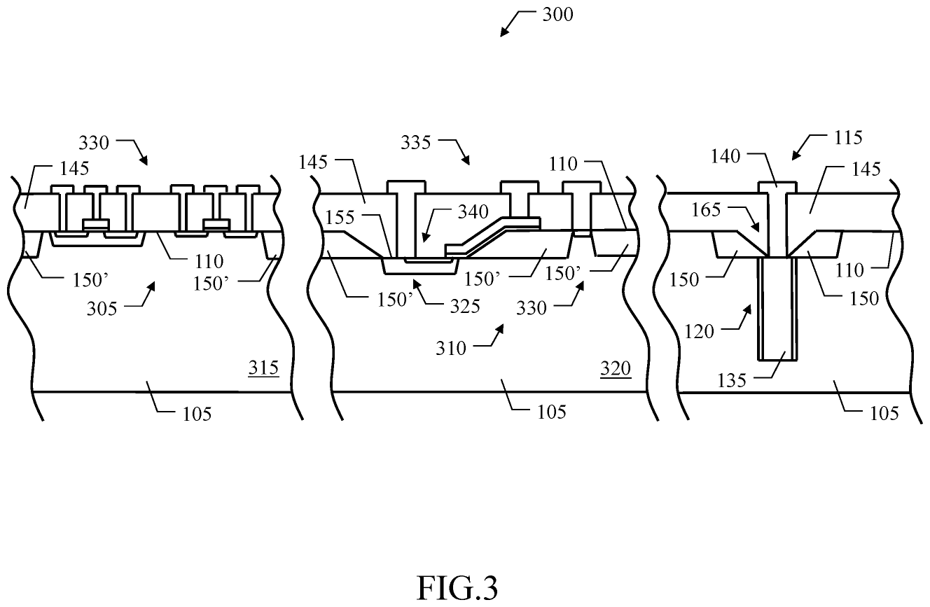

With reference now to FIG. 3, a schematic representation is shown in cross-section view of a further integrated device 300 according to an embodiment of the present disclosure (wherein elements in common with the preceding figures are denoted with the same references).

As above, the integrated device 300 is integrated on a chip 105 having a front surface 110. The integrated device 300 comprises a deep plug 115 (or more), with a deep trench 120 extending below a shallow trench 150. In this case, the integrated device 300 is of mixed type, comprising both low-voltage (or signal) components 305 (enlarged in the figure) and high-voltage (or power) components 310. The low-power components 305 are designed to work at relatively low voltages, whereas the high-voltage components 310 are designed to work at relatively high voltages; for example, the high voltages are 50-500 times the low voltages (such as 2-10V and 100-2,000V, respectively). For example, the integrated device 300 is of Bipolar-CMOS-DMOS (BCD) type, with a CMOS of the low-voltage components 305 and a DMOS of the high-voltage components 310 shown in the figure. The chip 105 has a low-voltage area 315 for the low-voltage components 305 and a high-voltage area 320 for the high-voltage components 310. One or more (further) shallow trenches, differentiated with the reference 150′, extend in the chip 105 from the front surface 110. The shallow trenches 150′ insulate the components integrated on the chip 105, comprising the low-voltage area 315 from the high-voltage area 320.

As usual, the low-voltage components 305 have their active regions that extend in the low-voltage area 315 from the front surface 110; for example, the active regions of the low-voltage components 305 comprise a body region, a source region and a drain region for a first MOS of the CMOS (to the left in the figure) and a source region and a drain region of a second (complementary) MOS of the CMOS (to the right in the figure). The low-voltage components 305 are then completed by a gate insulating layer and a gate region stacked on the front surface 110 over a channel region between each pair of source/drain regions.

The high-voltage components 310, instead, have at least part of their active regions, denoted as shallow active regions 325, which extend in the high-voltage area 320 from the shallow surface 155 of a selected (further) shallow trench 150′ (or more), as described in United States Patent Application Publication No. 2015/0130750 (the entire disclosure of which is herein incorporated by reference to the maximum extent allowable by law). In this way, the shallow active regions 325 are formed in a so-called Shallow Trench Active (STA) area under the shallow trench 150′. The high-voltage components 310 may also have other active regions, denoted as front active regions 330, which extend in the high-voltage area 320 from the front surface 110 as usual. For example, the shallow active regions 325 comprise a body region and a source region and the front active regions 330 comprise a drain contact region of the DMOS. The high-voltage components 310 are then completed by a gate insulating layer and a gate region stacked on the shallow surface 155 over a channel region between the source/drain regions and a drain junction between the body/drain regions, which gate insulating layer/region extend up to the front surface 110 on an interface surface of the shallow trench 150′ between the shallow surface 155 and the front surface 110. As above, a protective layer 145 covers the whole chip 105, with a trench contact 140 for the deep trench 120 (i.e., its conductive filler 135) crossing the protective layer 145 through a trench window 165 in the corresponding shallow trench 150. Moreover, similar components contacts 330 and 335 (crossing the protective layer 145 as well) are provided for the low-voltage components 305 and the high-voltage components 310, respectively; particularly, at least part of the shallow active regions 325 are contacted by one or more of the component contacts 335 crossing the protective layer 145 through a (component) window 340 in the corresponding shallow trench 150′.

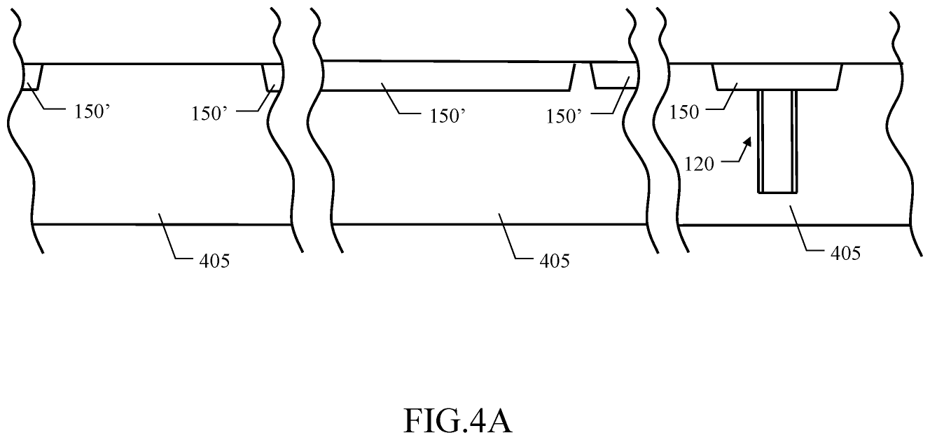

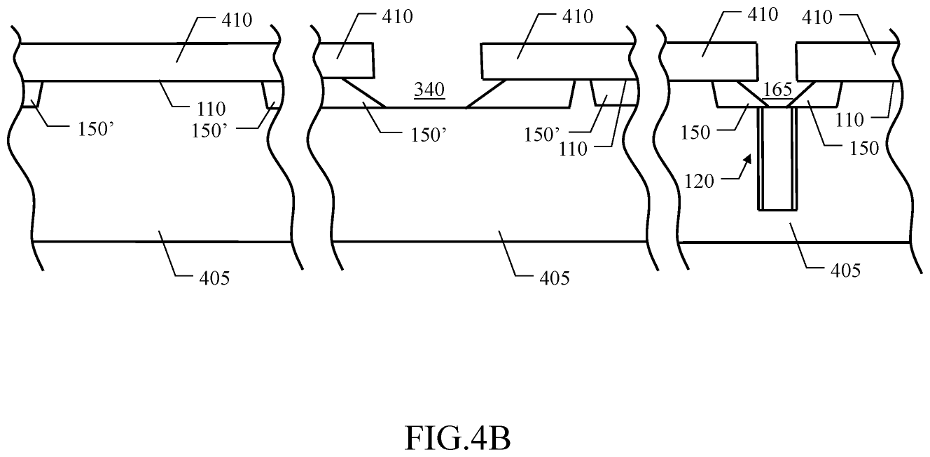

With reference now to FIG. 4A-FIG. 4B, the main steps are shown of a manufacturing process of the further integrated device according to an embodiment of the present disclosure.

Starting from FIG. 4A, as above the manufacturing process is performed at the level of a wafer 405 of semiconductor material, wherein the same structure is integrated simultaneously in a large number of identical areas thereof (only one referred to in the following for the sake of simplicity). The deep trench 120 and the corresponding shallow trench 150 are formed as described above; at the same time, the shallow trenches 150′ are formed together with the shallow trench 150.

Moving to FIG. 4B, a mask 410 is formed (for example, with photo-lithographic techniques) onto the wafer 405; the mask 410 leaves exposed a portion of the shallow trench 150 for contacting the deep trench 120 and a portion of the shallow trench 150′ for the next formation of the shallow active regions (of the high-voltage components). The insulating filler of the shallow trenches 150, 150′ is etched through the mask 410 to form the trench window 165 (for the deep trench 120) across the shallow trench 150 and the component window 340 (for the shallow active regions) across the shallow trench 150′. In this way, the additional operation required for forming the deep plug (i.e., opening the trench window 165 across the shallow trench 150) is performed together with the operation already used to form the integrated device (i.e., opening the component window 340 for the shallow active regions) without the need of any additional process step (and then with no added costs). Particularly, the etching is isotropic (for example, performed with wet etching techniques), so that it also acts in a direction parallel to the front surface 110 and then under the mask 410 (in addition to in a direction perpendicular to the front surface 110). As a result, an angle (i.e., the second angle) formed by the interface surface of the shallow trenches 150, 150′ at the (trench/component) windows 165, 340 with the front surface 110 is lower than an angle (i.e., the first angle) formed by a lateral surface of the shallow trenches 150, 150′ (for example, 20-70° and 80-90°, respectively); this reduces a concentration of electric field at the shallow active regions of the high-voltage components (where it is more critical), so as to improve their performance and reliability.

The process then continues as described in United States Patent Application Publication No. 2015/0130750, with the same process steps used to complete the low-voltage components and the high-voltage components that are also used to contact the deep trench 120. Briefly, a layer of gate oxide is thermally grown on the wafer 405, the body regions are implanted and diffused, a layer of doped polysilicon is deposited on the layer of gate oxide, the two layers are selectively etched to form the gate insulating layers and the gate regions, the drain regions, source regions and drain contact region are implanted and diffused, a layer of protective material is deposited onto the wafer and selectively etched to open corresponding windows for the component contacts (and for the trench contact), a layer of metal is deposited onto the wafer and selectively etched to form the component contacts (and the trench contact).

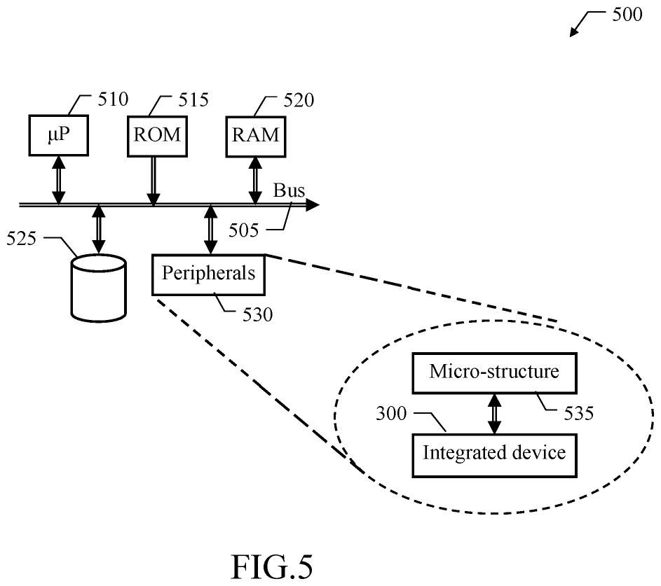

With reference now to FIG. 5, a schematic block diagram is shown of a system 500 incorporating the integrated device according to an embodiment of the present disclosure.

The system 500 (for example, a control unit for automotive applications) comprises several components that are connected among them through a bus structure 505 (with one or more levels). Particularly, one or more microprocessors (μP) 510 provide processing and orchestration functionalities of the system 500; a non-volatile memory (ROM) 515 stores basic code for a bootstrap of the system 500 and a volatile memory (RAM) 520 is used as a working memory by the microprocessors 510. The system has a mass-memory 525 for storing programs and data (for example, a flash E²PROM). Moreover, the system 500 comprises a number of controllers of peripheral, or Input/Output (I/O), units, 530 (such as a Wi-Fi WNIC, a Bluetooth transceiver, a GPS receiver, an accelerometer, a gyroscope and so on). Particularly, one or more of the peripherals 530 each comprises a micro (electro-mechanical) structure 535 (for example, one or more sensors/actuators) and the integrated device 300 for controlling the microstructure 535.

Naturally, in order to satisfy local and specific requirements, a person skilled in the art may apply many logical and/or physical modifications and alterations to the present disclosure. More specifically, although this disclosure has been described with a certain degree of particularity with reference to one or more embodiments thereof, it should be understood that various omissions, substitutions and changes in the form and details as well as other embodiments are possible. Particularly, different embodiments of the present disclosure may even be practiced without the specific details (such as the numerical values) set forth in the preceding description to provide a more thorough understanding thereof; conversely, well-known features may have been omitted or simplified in order not to obscure the description with unnecessary particulars. Moreover, it is expressly intended that specific elements and/or method steps described in connection with any embodiment of the present disclosure may be incorporated in any other embodiment as a matter of general design choice. Moreover, items presented in a same group and different embodiments, examples or alternatives are not to be construed as de facto equivalent to each other (but they are separate and autonomous entities). In any case, each numerical value should be read as modified according to applicable tolerances; particularly, unless otherwise indicated, the terms “substantially”, “about”, “approximately” and the like should be understood as within 10%, preferably 5% and still more preferably 1%. Moreover, each range of numerical values should be intended as expressly specifying any possible number along the continuum within the range (comprising its end points). Ordinal or other qualifiers are merely used as labels to distinguish elements with the same name but do not by themselves connote any priority, precedence or order. The terms include, comprise, have, contain, involve and the like should be intended with an open, non-exhaustive meaning (i.e., not limited to the recited items), the terms based on, dependent on, according to, function of and the like should be intended as a non-exclusive relationship (i.e., with possible further variables involved), the term a/an should be intended as one or more items (unless expressly indicated otherwise), and the term means for (or any means-plus-function formulation) should be intended as any structure adapted or configured for carrying out the relevant function.

For example, an embodiment provides an integrated device. However, the integrated device may be of any type (for example, of low-voltage type, high-voltage type, mixed type and so on). Moreover, the integrated device may be distributed by its supplier in raw wafer form, as a bare die, or in packages.

In an embodiment, the integrated device is integrated on a semiconductor body having a main surface. However, the semiconductor body may be of any type (for example, a monocrystalline substrate, an epitaxial layer grown on the substrate, an SOI substrate and so on).

In an embodiment, the integrated device comprises a deep plug. However, the integrated device may comprise any number of deep plugs, each used for any purpose (for example, to bias a substrate, collect parasitic currents from the substrate and so on).

In an embodiment, the deep plug comprises a deep trench extending in the semiconductor body to a deep depth from the main surface. However, the deep trench may have any shape (in transversal cross-section) and it may extend to any deep depth.

In an embodiment, the deep trench has a lateral surface that is coated with an insulating coating of electrically insulating material. However, the electrically insulating material may be of any type (for example, silicon oxide, silicon nitride, TEOS and so on).

In an embodiment, the coated deep trench is filled with a conductive filler of electrically conductive material. However, the electrically conductive material may be of any type (for example, doped polysilicon, metal and so on).

In an embodiment, the deep plug comprises a trench contact of electrical conductive material contacting the conductive filler. However, the trench contact may be of any type and of any material (for example, a pad, a ball, of metal, of doped polysilicon and so on) and it may contact the conductive filler in any way (for example, only on a portion thereof, on its totality and so on).

In an embodiment, the integrated device comprises a shallow trench extending in the semiconductor body from the main surface. However, the shallow trench may have any shape (in transversal cross-section) and size.

In an embodiment, the shallow trench has a shallow surface at a shallow depth from the main surface lower than the deep depth. However, the shallow surface may be of any type (for example, planar, concave, convex and so on) and the shallow depth may have any value (in either relative or absolute terms).

In an embodiment, the shallow trench is filled with an insulating filler of electrically insulating material. However, the electrically insulating material may be of any type (for example, silicon oxide, silicon nitride, TEOS and so on).

In an embodiment, the deep trench extends from the shallow surface to the deep depth. However, the deep trench may extend from the shallow surface in any way (for example, from any portion thereof or from its totality).

In an embodiment, the trench contact contacts the conductive filler through the shallow trench at the shallow surface. However, the trench contact may contact the conductive filler in any way through the shallow trench (for example, occupying only a part or the totality of a trench window opened across the shallow trench, and so on).

Further embodiments provide additional advantageous features, which may however be omitted at all in a basic implementation.

Particularly, in an embodiment, the shallow trench is coaxial with the deep trench. However, the possibility is not excluded of having the deep trench offset to the shallow trench.

In an embodiment, a transversal cross-section of the shallow trench is larger than a transversal cross-section of the deep trench. However, this result may be achieved in any way (for example, with the shallow trench having the same shape but larger than the deep trench, with the shallow trench having a different shape that surrounds the deep trench, with or without one or more contact points, and so on); in any case, the possibility is not excluded of having the shallow trench and the deep trench substantially with the same cross-section.

In an embodiment, a trench window across the shallow trench exposes a central portion of the conductive filler. However, the exposed central portion of the conductive filler may be of any type (for example, with any extent, symmetric or not around the longitudinal axis of the deep trench, and so on).

In an embodiment, the trench contact contacts the central portion of the conductive filler through the trench window. However, the possibility is not excluded of having the trench contact contacting only a portion of the central portion of the conductive filler.

In an embodiment, the integrated device comprises one or more further shallow trenches. However, the further shallow trenches may be in any number; moreover, the further shallow trenches may have any shape and size (either the same or different with respect to the shallow trench).

In an embodiment, the further shallow trenches insulate a low-voltage area and a high-voltage area of the semiconductor body. However, the two areas may have any shape and size.

In an embodiment, the low-voltage area comprises one or more low-voltage components of the integrated device designed to work at a low-voltage. However, the low-voltage components may be in any number and of any type (for example, CMOS, NMOS, PMOS, BJT and so on), and their low-voltage may have any value.

In an embodiment, the high-voltage area comprises one or more high-voltage components of the integrated device designed to work at a high-voltage higher than the low-voltage. However, the high-voltage components may be in any number and of any type (for example, DMOS, SCR and so on), and their high-voltage may have any value (in either relative or absolute terms).

In an embodiment, the low-voltage components comprises one or more active regions extending in the low-voltage area from the main surface. However, the active regions of the low-voltage components may be in any number and of any type (for example, body, source, drain, emitter, collector and so on).

In an embodiment, the high-voltage components comprise one or more active regions extending in the high-voltage area from the shallow surface of at least a selected one of the further shallow trenches. However, the active regions of the high-voltage components may be in any number and of any type (for example, body, source, drain, emitter, collector and so on); moreover, the active regions may extend from the shallow surface of any number of selected further shallow trenches in any way (for example, from any portion thereof or from its totality). In any case, the high-voltage components may have other active regions extending in the high-voltage area from the main surface (or all the active regions extending from the shallow surface).

In an embodiment, an interface surface between the main surface and the shallow surface (of the shallow trench and each of the further shallow trenches) forms an angle of 20-70° with the main surface. However, the possibility of having different values of this angle is not excluded.

An embodiment provides a system comprising at least one integrated device as above. However, the same structure may be integrated with other circuits in the same chip; the chip may also be coupled with one or more other chips, it may be mounted in intermediate products or it may be used in complex apparatus. In any case, the resulting system may be of any type (for example, for use in automotive applications, smartphones, computers and so on) and it may comprise any number of these integrated devices.

Generally, similar considerations apply if the integrated device and the system each one has a different structure or comprises equivalent components (for example, of different materials) or it has other operative characteristics. In any case, every component thereof may be separated into more elements, or two or more components may be combined together into a single element; moreover, each component may be replicated to support the execution of the corresponding operations in parallel. Moreover, unless specified otherwise, any interaction between different components generally does not need to be continuous, and it may be either direct or indirect through one or more intermediaries.

An embodiment provides a process for manufacturing the above-mentioned integrated device. However, the integrated device may be manufactured with any technologies, with masks being different in number and in type, or with other process parameters. Moreover, the above-described solution may be part of the design of an integrated device. The design may also be created in a hardware description language; moreover, if the designer does not manufacture chips or masks, the design may be transmitted by physical means to others.

In an embodiment, the process comprises forming a deep plug. However, the deep plug may be formed in any way (for example, with dedicated process steps, together with the process steps of other components of the integrated device and so on).

In an embodiment, the step of forming the deep plug comprises forming a deep trench extending in the semiconductor body to a deep depth from the main surface. However, the deep trench may be formed in any way (for example, by plasma etching, RIE etching, deep-RIE etching, sputter etching and so on).

In an embodiment, the step of forming the deep plug comprises coating a lateral surface of the deep trench with an insulating coating of electrically insulating material. However, the lateral surface may be coated in any way (for example, by growing, deposition, either selective or indiscriminate followed by patterning, and so on).

In an embodiment, the step of forming the deep plug comprises filling the coated deep trench with a conductive filler of electrically conductive material. However, the deep trench may be filled in any way (for example, by chemical-vapor deposition, galvanic deposition and so on).

In an embodiment, the step of forming the deep plug comprises forming a shallow trench extending in the semiconductor body from the main surface to a shallow surface (at a shallow depth lower than the deep depth). However, the shallow trench may be formed in any way (for example, by wet etching, dry etching and so on).

In an embodiment, the shallow trench is formed to have the deep trench extending from the shallow surface to the deep depth. However, the shallow trench may be formed in any way around the deep trench (for example, after forming the deep trench, before its formation and so on).

In an embodiment, the step of forming the deep plug comprises filling the shallow trench with an insulating filler of electrically insulating material. However, the shallow trench may be filled in any way (for example, by deposition, growing and so on).

In an embodiment, the step of forming the deep plug comprises forming a trench contact contacting the conductive filler at the shallow surface through the shallow trench. However, the trench contact may be formed in any way (for example, by deposition followed by patterning, selective deposition and so on).

Further embodiments provide additional advantageous features, which may however be omitted at all in a basic implementation.

Particularly, in an embodiment the step of forming the deep plug comprises forming the shallow trench after the steps of forming the deep trench (extending from the main surface), coating the lateral surface of the deep trench and filling the coated deep trench. However, the possibility is not excluded of forming the deep trench after the shallow trench (for example, when its insulating coating is formed by cold deposition).

In an embodiment, the step of forming the deep plug comprises opening a trench window across the shallow trench exposing at least part of the conductive filler. However, the trench window may be opened in any way (for example, by wet etching, dry etching and so on).

In an embodiment, the step of forming the deep plug comprises forming the trench contact across the trench window. However, the trench contact may be formed across the trench window in any (for example, through a part thereof via a window opened across a protective layer filling it, through the whole trench window and so on).

In an embodiment, the process comprises forming one or more further shallow trenches insulating a low-voltage area and a high-voltage area of the semiconductor body. However, the further shallow trenches may be formed in any way and at any time (either the same or different with respect to the shallow trench of the deep plug).

In an embodiment, the process comprises forming one or more low-voltage components of the integrated device (designed to work at a low-voltage) in the low-voltage area; the low-voltage components comprise one or more active regions extending in the low-voltage area from the main surface. However, the active regions of the low-voltage components may be formed in any way (for example, by implantation, diffusion and so on).

In an embodiment, the process comprises forming one or more high-voltage components of the integrated device (designed to work at a high-voltage higher than the low-voltage) in the high-voltage area; the high-voltage components comprise one or more active regions extending in the high-voltage area from the shallow surface of at least a selected one of the further shallow trenches. However, the active regions of the high-voltage components may be formed in any way (for example, with the same process steps of the low-voltage components, with dedicated process steps and so on).

In an embodiment, the process comprises opening a component window across the selected further shallow trench exposing at least part of the shallow surface thereof. However, the component window may be opened in any way (either the same or different with respect to the trench window).

In an embodiment, the component window is opened together with the trench window. However, the possibility is not excluded of opening the trench window and the component window independently.

In an embodiment, the process comprises forming the active regions of the high-voltage components across the component window. However, the active regions may be formed across the component windows in any way (for example, with the same process steps of the other active regions of the high-voltage components, with dedicated process steps and so on).

In an embodiment, the trench window and the component window are opened by isotropic etching. However, the possibility is not excluded of opening the trench window and/or the component window by anisotropic etching.

Generally, similar considerations apply if the same solution is implemented with an equivalent method (by using similar steps with the same functions of more steps or portions thereof, removing some non-essential steps or adding further optional steps); moreover, the steps may be performed in a different order, concurrently or in an interleaved way (at least in part).

1. An integrated device, comprising:
a semiconductor body having a main surface and a thickness; and
a deep plug, comprising:
a deep trench extending into the semiconductor body less than said thickness to a deep depth from the main surface, the deep trench having a lateral surface coated with an insulating coating of electrically insulating material and a conductive filler of electrically conductive material that fills the coated deep trench and makes physical and electrical contact with the semiconductor body at a bottom of the deep trench;
a trench contact of electrical conductive material contacting the conductive filler; and
a shallow trench extending into the semiconductor body from the main surface, the shallow trench having a shallow surface at a shallow depth from the main surface that is less than the deep depth, the shallow trench filled with an insulating filler of electrically insulating material;
wherein the deep trench extends from the shallow trench at the shallow surface to the deep depth; and
wherein the trench contact contacts the conductive filler through a trench window present in the insulating filler for the shallow trench at the shallow surface.

2. The integrated device according to claim 1, wherein the shallow trench is coaxial with the deep trench, wherein a cross-section of the shallow trench taken parallel to the main surface is larger than a cross-section of the deep trench taken parallel to the main surface, and wherein the trench window across the shallow trench exposes a central portion of the conductive filler, the trench contact contacting the central portion of the conductive filler through the trench window.

3. The integrated device according to claim 1, further comprising:
a first further shallow trench insulating a low-voltage area of the semiconductor body;
a second further shallow trench insulating a high-voltage area of the semiconductor body;
wherein the low-voltage area comprises:
one or more low-voltage components of the integrated device designed to work at a low-voltage; and
one or more active regions extending in the low-voltage area from the main surface;
wherein the high-voltage area comprises:
one or more high-voltage components of the integrated device designed to work at a high-voltage higher than the low-voltage; and
one or more active regions extending in the high-voltage area from the shallow surface of at least a selected one of the further shallow trenches.

4. The integrated device according to claim 3, wherein an interface surface between the main surface and the shallow surface of the shallow trench and the second further shallow trenches forms an angle of 20-70° with the main surface.

5. The integrated device according to claim 1, wherein a surface of the trench window forms an angle with the main surface that is less than an angle formed by an interface surface between the main surface and the shallow surface of the shallow trench.

6. The integrated device according to claim 1, further comprising:
a further shallow trench insulating a low-voltage area of the semiconductor body;
wherein the low-voltage area comprises:
one or more low-voltage components of the integrated device designed to work at a low-voltage; and
one or more active regions extending in the low-voltage area from the main surface.

7. A system, comprising at least one integrated device according to claim 6.

8. The integrated device according to claim 1, further comprising:
a further shallow trench insulating a high-voltage area of the semiconductor body;
wherein the high-voltage area comprises:
one or more high-voltage components of the integrated device designed to work at a high-voltage higher than the low-voltage; and
one or more active regions extending in the high-voltage area from the shallow surface of at least a selected one of the further shallow trenches.

9. A system, comprising at least one integrated device according to claim 7.

10. A system, comprising at least one integrated device according to claim 1.

11. The integrated device according to claim 1, wherein a sidewall of the shallow trench extending from the main surface to the shallow surface forms a first angle with respect to the shallow surface, and wherein a sidewall of the trench window present in the insulating filler forms a second angle with respect to the shallow surface that is different from the first angle.

12. The integrated device according to claim 11, wherein the first angle is steeper than the second angle.

13. A process for manufacturing an integrated device that is integrated on a semiconductor body having a main surface and a thickness, comprising:
forming a deep plug by:
forming a deep trench extending into the semiconductor body less than said thickness to a deep depth from the main surface;
coating a lateral surface of the deep trench with an insulating coating of electrically insulating material;
filling the coated deep trench with a conductive filler of electrically conductive material to make physical and electrical contact with the semiconductor body at a bottom of the deep trench;
forming a shallow trench extending in the semiconductor body from the main surface to a shallow surface at a shallow depth less than the deep depth to have the deep trench extending from the shallow trench at the shallow surface to the deep depth;
filling the shallow trench with an insulating filler of electrically insulating material; and
forming a trench contact contacting the conductive filler through a trench window in the electrically insulating material at the shallow surface through the shallow trench.

14. The process according to claim 13, wherein forming the deep plug further comprises:
forming the shallow trench after forming the deep trench extending from the main surface, coating the lateral surface of the deep trench and filling the coated deep trench;
opening the trench window across the shallow trench exposing at least part of the conductive filler; and
forming the trench contact across the trench window.

15. The process according to claim 13, further comprising:
forming a further shallow trench insulating a low-voltage area of the semiconductor body; and
forming one or more low-voltage components of the integrated device designed to work at a low-voltage in the low-voltage area, the low-voltage components comprising one or more active regions extending in the low-voltage area from the main surface.

16. The process according to claim 13, further comprising:
forming a further shallow trench insulating a high-voltage area of the semiconductor body, and
forming one or more high-voltage components of the integrated device designed to work at a high-voltage higher than the low-voltage in the high-voltage area, the high-voltage components comprising one or more active regions extending in the high-voltage area from the shallow surface of at least a selected one of the further shallow trenches.

17. The process according to claim 16, further comprising:
opening a component window across the further shallow trench exposing at least part of the shallow surface thereof together with the trench window; and
forming the active regions of the high-voltage components across the component window.

18. The process according to claim 17, wherein opening the component window comprises performing an isotropic etching.

19. The process according to claim 13, wherein a sidewall of the shallow trench extending from the main surface to the shallow surface forms a first angle with respect to the shallow surface, and wherein a sidewall of the trench window present in the electrically insulating material forms a second angle with respect to the shallow surface that is different from the first angle.

20. The process according to claim 19, wherein the first angle is steeper than the second angle.
